(19) United States
(12) Patent Application Publication
(10) Pub. No.: US 2013/0243019 A1
(43) Pub. Date: Sep. 19, 2013

(54) LASER DIODE ARRAY AND LASER DIODE UNIT

(71) Applicant: SONY CORPORATION, Tokyo (JP)

(72) Inventors: Kazuya Wakabayashi, Kanagawa (JP); Tomoki Ono, Kanagawa (JP)

(73) Assignee: SONY CORPORATION, Tokyo (JP)

(21) Appl. No.: 13/796,656

(22) Filed: Mar. 12, 2013

(30) Foreign Application Priority Data
Mar. 15, 2012 (JP) 2012-058213

(51) Int. Cl. H01S 5/024

(52) U.S. Cl. CPC H01S 5/024
USPC 372/36

(57) ABSTRACT

A laser diode array includes: a heat dissipator; a plurality of submounts disposed independently of one another on the heat dissipator; and a plurality of laser diode devices including two or more kinds of laser diode devices with different oscillation wavelengths, the laser diode devices being disposed on the respective submounts, and being electrically connected to one another.

### CROSS REFERENCES TO RELATED APPLICATIONS

The present application claims priority to Japanese Priority Patent Application JP 2012-058213 filed in the Japan Patent Office on Mar. 15, 2012, the entire content of which is hereby incorporated by reference.

### BACKGROUND

The present disclosure relates to a laser diode array including a plurality of laser diode devices on a heat sink, and a laser diode unit including the laser diode array.

A laser diode is used as a light source for a display or the like because of its small light-emitting point and its sharp spectrum (its high color rendering properties). For example, in Japanese Unexamined Patent Application Publication No. 2006-32406, a laser array including a plurality of laser diode devices which are one-dimensionally arranged is used as a high-power laser.

However, when the laser diode is used as a light source, there are two issues, i.e., screen glare (speckle noise) and deterioration in characteristics due to heat generation.

A typical laser diode has a characteristic in which an oscillation wavelength thereof is shifted to a longer wavelength with an increase in an internal temperature of an active layer. For example, in Japanese Unexamined Patent Application Publication No. 2008-4743, there is disclosed a method of reducing speckle noise with use of the characteristics. In the method, distances between light-emitting points are varied to cause thermal interference in an array laser, and a thermal distribution is provided to vary wavelengths from respective light-emitting points, thereby expanding an emission spectrum. Thus, speckle noise is reduced.

Moreover, for example, in Japanese Unexamined Patent Application Publication No. H9-252166, there is disclosed a configuration of a semiconductor light-emitting device in which chips (laser diode devices) are separated, and a heat dissipater (heat sink) disposed between a substrate and the chips has a smaller thickness than a distance between chips to thereby reduce thermal interference.

### SUMMARY

However, in a technique of expanding a spectrum of a laser diode device through providing a thermal distribution as in Japanese Unexamined Patent Application Publication No. 2008-4743, it is difficult to produce a thermal distribution large enough to sufficiently reduce speckle noise, and an issue, i.e., a decline in reliability of a device in a high-temperature region arises. Moreover, in the semiconductor light-emitting device in Japanese Unexamined Patent Application Publication No. H9-252166, a reduction in thermal interference causes an increase in coherence of light from each light-emitting point, resulting in an increase in speckle noise.

It is desirable to provide a laser diode array capable of reducing speckle noise and suppressing deterioration in characteristics of a laser diode device, and a laser diode unit including the laser diode array.

According to an embodiment of the disclosure, there is provided a laser diode array including: a heat dissipator; a plurality of submounts disposed independently of one another on the heat dissipator; and a plurality of laser diode devices including two or more kinds of laser diode devices with different oscillation wavelengths, the laser diode devices being disposed on the respective submounts, and being electrically connected to one another.

According to an embodiment of the disclosure, there is provided a laser diode unit including a plurality of laser diode arrays, each of the laser diode arrays including: a heat dissipator; a plurality of submounts disposed independently of one another on the heat dissipator; and a plurality of laser diode devices including two or more kinds of laser diode devices with different oscillation wavelengths, the laser diode devices being disposed on the respective submounts, and being electrically connected to one another.

In the laser diode array and the laser diode unit according to the embodiments of the disclosure, the plurality of laser diode devices are disposed on the heat dissipator with the respective submounts in between; therefore, heat dissipation efficiency of the laser diode devices is improved. Moreover, when laser diode devices with different oscillation wavelengths are disposed in the laser diode array, a wavelength width of the laser diode array is increased, and coherency is reduced.

In the laser diode array and the laser diode unit according to the embodiments of the disclosure, since the plurality of laser diode devices are disposed on the heat dissipator with the respective submounts in between, heat dissipation efficiency of the laser diode devices is improvable, and deterioration in characteristics due to heat generation is allowed to be suppressed. Moreover, since the laser diode devices with different wavelengths are disposed on the heat dissipator, the wavelength width of the laser diode array is increased, and speckle noise is allowed to be reduced.

It is to be understood that both the foregoing general description and the following detailed description are exemplary, and are intended to provide further explanation of the technology as claimed.

Additional features and advantages are described herein, and will be apparent from the following Detailed Description and the figures.

### BRIEF DESCRIPTION OF THE FIGURES

The accompanying drawings are included to provide a further understanding of the technology, and are incorporated in and constitute a part of this specification. The drawings illustrate embodiments and, together with the specification, serve to explain the principles of the technology.

FIG. 1 is a perspective view illustrating a configuration of a laser diode array according to an embodiment of the disclosure.

FIG. 2 is a sectional view of the laser diode array taken along a line I-I of FIG. 1.

FIG. 3 is a sectional view of a device illustrated in FIG. 1.

FIG. 4 is a characteristic diagram illustrating a relationship between device interval and temperature increase.

FIG. 5 is a characteristic diagram illustrating a relationship between spectrum width and speckle contrast.

FIGS. 6A and 6B are schematic views illustrating connection of devices located at both ends of the laser diode array illustrated in FIG. 1.

FIG. 7 is a perspective view illustrating a configuration of a laser diode array according to a modification of the disclosure.

FIG. 8 is a perspective view illustrating a configuration of a laser diode unit including a plurality of laser diode arrays illustrated in FIG. 1 or 7.

FIG. 9 is a perspective view describing mounting of the laser diode array in the laser diode unit illustrated in FIG. 8.

FIG. 10 is a perspective view illustrating another configuration of the laser diode unit including a plurality of laser diode arrays illustrated in FIG. 1 or 7.

### DETAILED DESCRIPTION

A preferred embodiment of the disclosure will be described in detail below referring to the accompanying drawings. It is to be noted that description will be given in the following order.

1. Embodiment
1-1. Configuration of laser diode array
1-2. Manufacturing method

2. Modification

3. Application Examples

### 1. EMBODIMENT

### 1-1. Configuration of Laser Diode Array

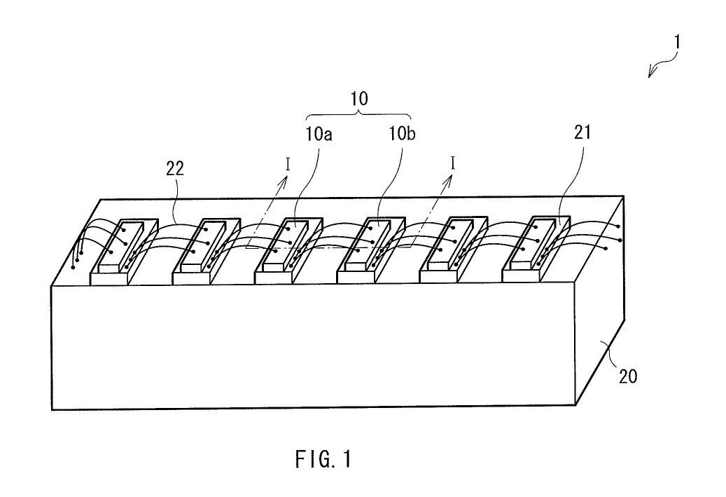

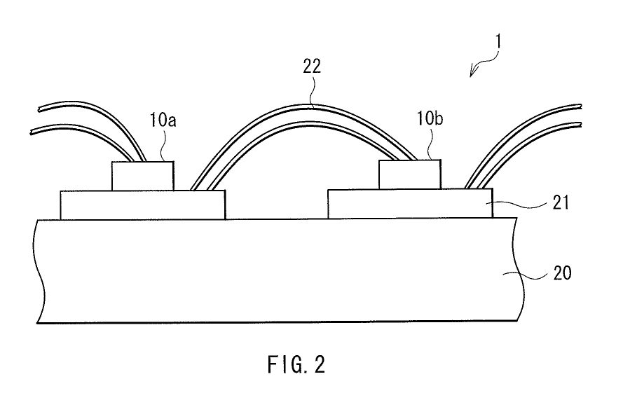

FIG. 1 illustrates an entire configuration of a laser diode array (a laser diode array 1) according to an embodiment of the disclosure. FIG. 2 illustrates a sectional configuration taken along a line I-I in FIG. 1. In the laser diode array 1, a plurality of laser diode devices (devices 10) are mounted along one direction on a heat dissipator (a heat sink 20) with submounts 21 in between. The submounts 21 are disposed independently of one another, and in this case, one device 10 is disposed on one submount 21. The devices 10 are connected to one another in series. More specifically, as will be described in detail later, for example, a first electrode (for example, a p-side electrode 13) of a pair of electrodes of a device 10a and a second electrode (for example, an n-side electrode 14) of a pair of electrodes of a device 10b are electrically connected to each other through a wire 22 (refer to FIG. 2).

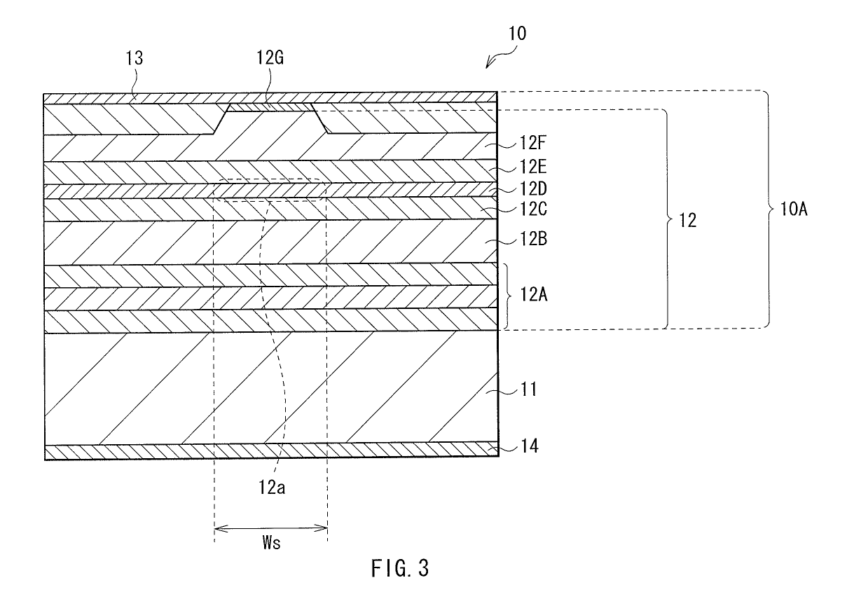

FIG. 3 illustrates a sectional configuration of the device 10. The device 10 is, for example, an edge-emitting laser diode device, and includes, on one surface (an upper surface) of a substrate 11, a laser structure section 10A configured of a semiconductor laminate structure 12 and a p-side electrode 13 formed on the semiconductor laminate structure 12. An n-side electrode 14 is disposed on the other surface (a lower surface) of the substrate 11.

In the device 10, the semiconductor laminate structure 12 disposed on the upper surface of the substrate 11 made of, for example, GaAs includes, for example, a buffer layer 12A, an n-type cladding layer 12B, an n-type guide layer 12C, an active layer 12D, a p-type guide layer 12E, a p-type cladding layer 12F, and a contact layer 12G in this order of closeness to the substrate 11. The n-type electrode 14 disposed on the lower surface of the substrate 11 is electrically connected to the n-type cladding layer 12A, and the p-type electrode 14 is electrically connected to the contact layer 12G.

The semiconductor laminate structure 12 is made of, for example, an AlGaInP-based material emitting light in a red region. As used herein, the term “AlGaInP-based compound semiconductor” refers to a quaternary semiconductor including one or both of aluminum (Al) and gallium (Ga) from Group 3B elements and one or both of indium (In) and phosphorus (P) from Group 5B elements in the long form of the periodic table of the elements, and examples of the AlGaIn-based compound semiconductor include an AlGaInP mixed crystal, a GaInP mixed crystal, and an AlInP mixed crystal. These mixed crystals may include an n-type impurity such as silicon (Si) or selenium (Se) or a p-type impurity such as magnesium (Mg), zinc (Zn), or carbon (C), if necessary. The device 10 emits light with a wavelength of about 630 nm to about 645 nm both inclusive. It is to be noted that an oscillation wavelength of the device 10 is not limited thereto, and the oscillation wavelength of the device 10 may be within a range of about 600 nm to about 630 nm both inclusive or a range of about 645 nm to about 700 nm both inclusive. Moreover, in addition to the AlGaInP-based material, a III-N-based material such as an AlInGaN-based material may be used. The device 10 has, for example, a width of about 0.3 mm to about 3 mm both inclusive, a length of about 0.3 mm to about 3 mm both inclusive, and a thickness of about 50 μm to about 300 μm both inclusive.

The heat sink 20 is made of, for example, a material having thermal conductivity and electrical conductivity such as copper (Cu) (with a linear expansion coefficient of 16.8×10⁻⁶/° C.), and, for example, a thin film made of gold (Au) is deposited on a surface of the heat sink 20. Thermal conductivity is a necessary characteristic to release a large amount of strong heat generated in the laser diode device to maintain the laser diode device at an appropriate temperature, and electrical conductivity is a necessary characteristic to efficiently conduct a current to the laser diode device.

The submounts 21 are made of an insulating material. More specifically, for example, aluminum nitride (AlN), silicon carbide (SiC), or the like is used. Each of the submounts 21 has, for example, a width of about 0.3 mm to about 4 mm both inclusive, a length of about 0.5 mm to about 5 mm both inclusive, and a thickness of about 50 μm to about 500 μm both inclusive. Metal thin films made of titanium (Ti), platinum (Pt), or Au are formed on a front surface and a back surface of each of the submounts 21, and the metal thin films on the front surface and the back surface are bonded to the device 10 and the heat sink 20, respectively, with solder. Examples of the solder used herein include gold-tin (AuSn) solder and tin-silver (SnAg) solder.

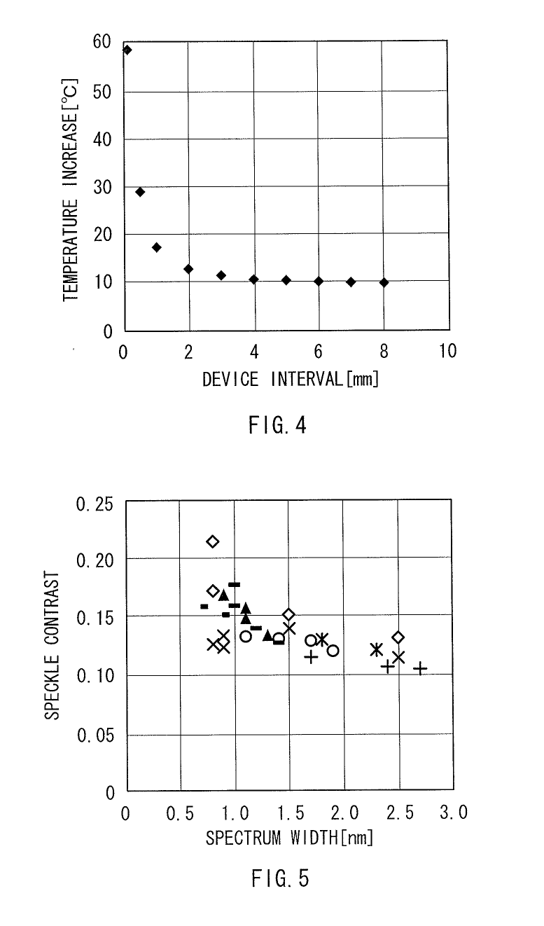

As described above, the submounts 21 are disposed separately from one another, and are arranged on the heat sink 20 at predetermined intervals. FIG. 4 illustrates a relationship between arrangement interval and temperature increase while the devices 10 emit light. As can be seen from FIG. 4, when a distance between the devices 10 is increased, an increase in temperature of each of the devices 10 is suppressed. More specifically, when each interval between the devices 10 is about 2 mm, an increase in temperature while the devices 10 emit light is about 10° C., and the temperature of each device 10 is hardly affected by the adjacent devices 10. In the case where each interval between the devices 10 is smaller than about 2 mm, thermal interference from the adjacent devices 10 is highly influential, and easily causes deterioration in characteristics. Moreover, when each interval between the devices 10 is increased to be about 2 mm or more, for example, in the case where the laser diode array 1 according to the embodiment is used in an illumination device of a projector, light is easily uniformized in the projector using a fly-eye lens or the like. Moreover, a high-priced lens such as a microlens array is not necessary, thereby resulting in a reduction in cost.

An upper limit of each interval between the devices 10 is preferably about 10 nm. For example, in the case where each interval between the devices 10 is larger than about 10 mm, it is necessary to increase light emission intensity per device to secure necessary light emission intensity in the same area, and this may cause damage to a laser facet. On the other hand, in the case where the devices 10 are used without increasing light emission intensity per device, light emission intensity per unit area is reduced, and it is necessary to upsize an entire light source accordingly. Therefore, each interval between the devices 10 is preferably within a range of about 2 mm to about 10 mm both inclusive.

As an example of arrangement of the devices 10 at intervals within the above-described range in the laser diode array 1, the devices 10 are arranged at 4-mm intervals on the heat sink 20 with a width of, for example, 35 mm with the submounts 21 in between. At this time, eight devices 10 are mounted on the heat sink 20.

It is to be noted that a plurality of devices 10 mounted on one heat sink 20 have slightly different oscillation wavelengths from one another, and a half-width of a wavelength spectrum of a superimposition of the oscillation wavelengths is adjusted to be about 2 nm or more. Thus, in the laser diode array 1 according to the embodiment, two or more kinds of devices 10 with different emission spectra from one another are arranged on one heat sink 20 to allow the spectra thereof to be superimposed on one another. Accordingly, a wavelength width of the entire laser diode array 1 is increased, and coherency declines. As a result, speckle noise is reduced. FIG. 5 illustrates a relationship between a spectrum width of the laser diode array 1 and speckle contrast. As can be seen from FIG. 5, when the spectrum width is within a range of about 2 nm to about 3 nm both inclusive, a sufficient effect on suppressing speckle contrast is obtainable.

The wavelength width of laser light emitted from each of the devices 10 in the laser diode array 1 is about 1 nm. As an example of a combination of the devices 10 in the laser diode array 1, for example, as described above, in the case where eight devices 10 are mounted on one heat sink 20, the devices 10 with oscillation wavelengths different by, for example, 0.5 nm from one another are used. When the eight devices 10 with oscillation wavelengths different by 0.5 nm from one another are selected and mounted, the spectrum width of the laser diode array 1 is about 4.5 nm (1 nm+0.5 nm×(8−1)) as a whole.

An example of a method of manufacturing the laser diode array 1 according to the embodiment will be described below. First, for example, the substrate 11 made of GaN is prepared, and, for example, semiconductor layers including the active layer 12D made of an AlGaInP-based material are grown on the front surface of the substrate 11 by, for example, an MOCVD (Metal Organic Chemical Vapor Deposition) method to form the semiconductor laminate structure 12. Next, a metal layer made of Ti, Pt, Au, or the like is laminated on the semiconductor laminate structure 12 by, for example, an evaporation method to form the p-side electrode 13.

Then, an Au-germanium (Ge) array layer or the like is formed on the back surface of the substrate 11 by, for example, an evaporation method to form the n-side electrode 14.

After that, separation and cleavage is performed to form a pair of resonator facets, and then the resonator facets are subjected to facet coating as appropriate. More specifically, for example, dielectric films made of Al₂O₃ or the like are deposited on the resonator facets by an evaporation method to adjust reflectivity of the resonator facets. Thus, the laser diode device (the device 10) illustrated in FIG. 3 is completed.

Next, each device 10 is disposed on each submount 21 made of AlN on which AuSn solder is evaporated to allow the p-side electrode 13 to be in contact with the submount 21, and then the device 10 and the submount 21 is heated by, for example, a heater to be integrated (into a laser-on-submount, i.e., LOS). Electrode probes are set up at a p-side (a metalized surface of an upper surface of the submount) and an n-side (the n-side electrode 14 of the device 10) of the LOS to pass a current through the device 10, and an oscillation wavelength at a predetermined current value of the device 10 is measured. Thus, the devices 10 are classified by wavelength.

In the case where a sufficient wavelength distribution is not obtained, a crystal is grown on the GaAs substrate again. At this time, the composition of Ga or In in the active layer 12D is adjusted to vary the oscillation wavelength after fabricating the device 10. This process is repeatedly performed until a necessary oscillation wavelength width is obtained. The wavelength of the device 10 may be measured before the device 10 is mounted on the submount 21, but the wavelength of the device 10 may vary by stress at the time of mounting. Therefore, it is desirable to measure the wavelength after the device 10 and the submount 21 are bonded together.

Next, the devices 10 (LOSs) with different wavelengths from one another are selected from a plurality of devices 10 classified by wavelength, and are accurately bonded, at 4-mm intervals, onto the heat sink 20 having a metal-plated surface with, for example, SnAg solder.

Then, the devices 10 are electrically connected to one another in series through the wires 22 made of, for example, Au. More specifically, as illustrated in FIG. 2, the n-side (the n-side electrode 14) of the device 10a and the p-side (herein, a metal in contact with the p-side electrode 13) of the device 10b are connected to each other through the wire 22. Thus, the laser diode array 1 illustrated in FIG. 1 is completed.

As described above, the devices 10 in the laser diode array 1 according to the embodiment are connected to one another in series. When the devices 10 are connected to one another in series in such a manner, even in the case where an operation voltage varies during crystal growth or a manufacturing process, the devices 10 are operable according to an operation current. Moreover, the devices 10 are allowed to be driven at a small current for an entire unit. Further, even in the case where one of the devices 10 in the laser diode array 1 is short-circuited and damaged, not all the devices 10 stop light emission, and the laser diode array 1 is allowed to be driven with use of undamaged devices 10.

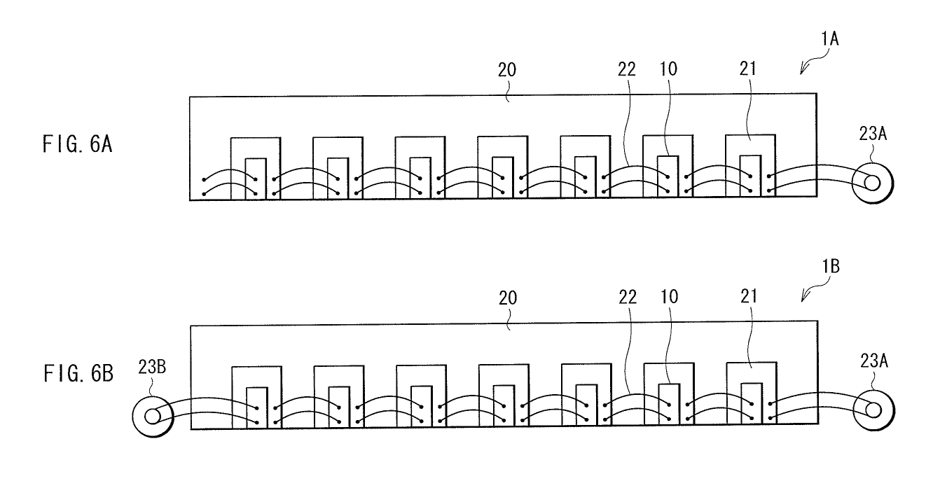

It is to be noted that, as illustrated in FIG. 6A, as connection of the devices 10 located at both ends of the laser diode array 1, the device 10 located at one of the ends of the laser diode array 1 may be connected to an electrode pin 23A, and the device 10 located at the other end of the laser diode array 1 may be connected to the heat sink 20 with electrical conductivity. Moreover, as illustrated in FIG. 6B, the devices 10 located at both ends of the laser diode array 1 may be connected to respective independent electrode pins 23A and 23B. The device 10 may be directly connected to the electrode pin 23A (or 23B) through the wire 22; however, the device 10 may be connected to the electrode pin 23A (or 23B) through, for example, a lead wire, a flexible electrode, or the like.

Moreover, in the case where the devices 10 in the laser diode array 1 are connected to one another in series as in the embodiment, an issue of a large difference between light outputs from the devices 10 may be caused. In this case, adjustment is possible through varying stripe widths Ws or resonator lengths 1 of the devices 10. For example, in the case where an AlGaInP-based material is used, light emission efficiency pronouncedly declines at a shorter wavelength than about 640 nm. Therefore, light intensity pronouncedly declines at a wavelength shorter than about 640 nm. In this case, the stripe width Ws of the device 10 of a short wavelength which causes a decline in light emission efficiency is reduced. Moreover, when the device 10 with a shorter resonator length l is used, current density during operation is increased to improve a light output.

When a predetermined voltage is applied between the n-side electrode 14 (the n-side) and the p-side electrode 13 (the p-side) in each of the devices 10 configuring the laser diode array 1 according to the embodiment, a current is injected into the active layer 12 to allow the device 10 to emit light by the recombination of electrons and holes. The light is reflected by a pair of resonator facets, and travels back and forth between the pair of resonator facets to cause laser oscillation. Thus, the light exits from the device 10 as a laser beam.

In a laser diode array in related art, the above-described various techniques are used to reduce deterioration in characteristics of the device due to speckle noise or thermal interference caused by coherent light interference. However, in any of the techniques, it is difficult to sufficiently reduce speckle noise and deterioration in characteristics of the device, and it is difficult to solve these two issues concurrently.

On the other hand, in the embodiment, the plurality of devices 10 are mounted on the heat sink 20 with the respective submounts 21 in between; therefore, heat dissipation efficiency is improved, and thermal interference by the adjacent devices 10 is reduced. Moreover, since a combination of two or more kinds of devices 10 with different oscillation wavelengths from one another is used in the laser diode array 1, the wavelength width of the entire laser diode array 1 is increased; therefore, coherency of the laser diode array 1 is allowed to be reduced.

Thus, in the laser diode array 1 according to the embodiment, a plurality of devices 10 are disposed on the heat sink 20 with the respective independent submounts 21 in between; therefore, heat dissipation efficiency of the devices 10 is improvable. Thus, deterioration in characteristics due to thermal interference of the adjacent devices 10 is suppressed. Moreover, since the devices 10 with different wavelengths from one another are combined together, the width of the oscillation wavelength of the laser diode array 1 is allowed to be increased, and speckle noise is allowed to be reduced.

Moreover, when the devices 10 are arranged at equal intervals within a predetermined range, in particular, at intervals of about 2 mm to about 10 mm both inclusive, heat of the devices 10 is allowed to be efficiently dissipated while maintaining light emission intensity of the devices 10 without upsizing an entire light source. Further, when the devices 10 with different oscillation wavelengths from one another are combined together to allow the wavelength width (half-width) of the laser diode array 1 to be about 2 nm, speckle noise is allowed to be efficiently reduced.

Next, a modification of the above-described embodiment will be described below. Like components are denoted by like numerals as of the above-described embodiment and will not be further described, and effects common to the above-described embodiment and the modification will not be further described.

### 2. MODIFICATION

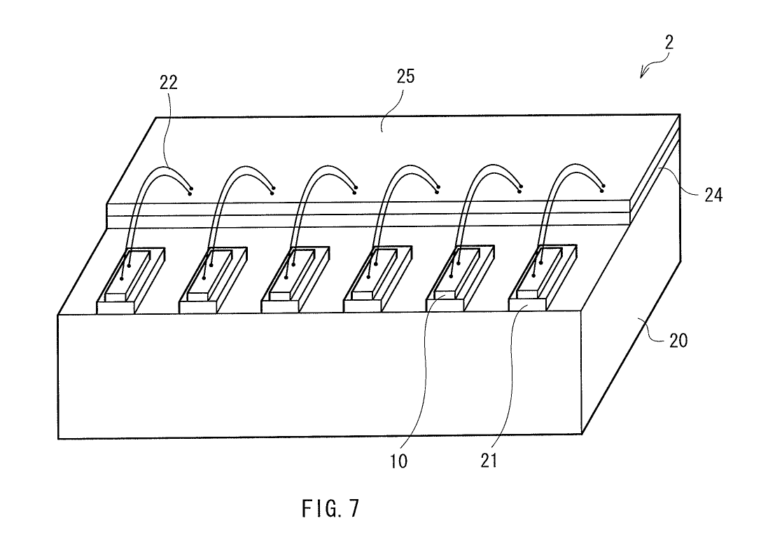

FIG. 7 illustrates an entire configuration of a laser diode array 2 according to a modification. The laser diode array 2 according to the modification is different from the laser diode array 1 according to the above-described embodiment in that a plurality of devices 10 mounted on the heat sink 20 are connected to one another in parallel.

As illustrated in FIG. 7, the p-side electrode 13 of each of the devices 10 is bonded onto the upper surface of each of the submounts 21 (to form an LOS), and the device 10 is connected to the heat sink 20, and the n-side of the LOS is a surface of the n-side electrode 14 (refer to FIG. 3). It is to be noted that the submount 21 is made of a conductive material or an insulating material. In the case where the submount 21 is made of an insulating material, a surface of the submount 21 is coated with a conductive material to allow the p-side electrode 13 of the device 10 and the heat sink 20 to be electrically connected to each other. Alternatively, the p-side electrode 13 of the device 10 and the heat sink 20 may be electrically connected to each other through a wire drawn from the upper surface of the submount 21. For example, the n-side electrodes 14 of the devices 10 are connected to one another through an electrode plate 25 fixed on the heat sink 20 with an insulating plate 24 in between and the wires 22. It is to be noted that, as the electrode plate 25, for example, a copper plate having a gold-plated surface may be used.

In the laser diode array 2 according to the modification, even in the case where one of the devices 10 in the laser diode array 2 has an open-circuit failure, not all the devices 10 stop light emission, and undamaged devices 10 are allowed to be driven. Moreover, typically, in the case where a voltage varies during crystal growth or a manufacturing process, an increase in a resistance value at a crystal interface or in a crystal frequently takes place, thereby frequently causing heat generation during operation. When the laser diode array 1 according to the above-described embodiment operates at a constant current, the device 10 with a higher operation voltage causes larger heat generation; therefore, the rate of deterioration may vary between the devices 10 in the laser diode array 1. On the other hand, in the modification, the devices 10 are so mounted as to be electrically connected to one another in parallel to equalize the voltage values of the devices 10. Therefore, in addition to the effects in the above-described embodiment, a current flowing through the device 10 with a high rate of deterioration is reduced to suppress variations in longevity between the devices 10.

### 3. APPLICATION EXAMPLES

### Application Example 1

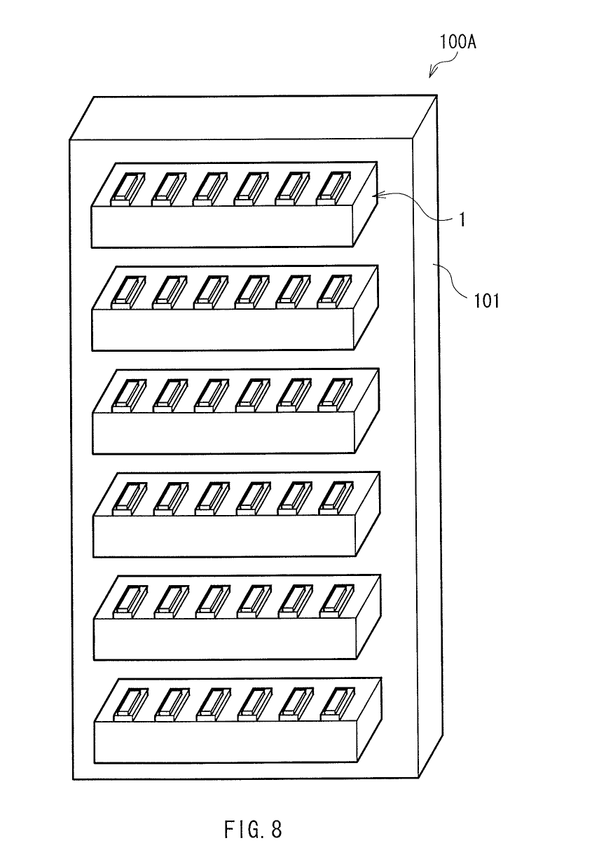

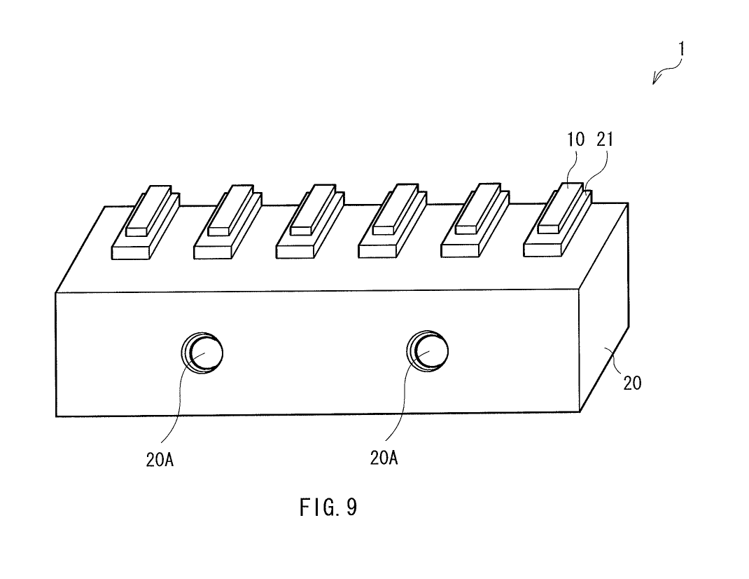

FIG. 8 illustrates a configuration example of a laser diode unit 100A using the laser diode arrays 1 and 2 according to the above-described embodiment and the above-described modification. In the laser diode unit 100A, for example, six laser diode arrays 1 described above are one-dimensionally arranged along a direction orthogonal to a direction where the devices 10 are mounted on the heat sink 20. As illustrated in FIG. 9, a tapped hole 20A is formed on a side surface, i.e., a surface orthogonal to the surface where the devices 10 are mounted of the heat sink 20, and the laser diode array 1 is fixed to a base plate 101 by a screw.

### Application Example 2

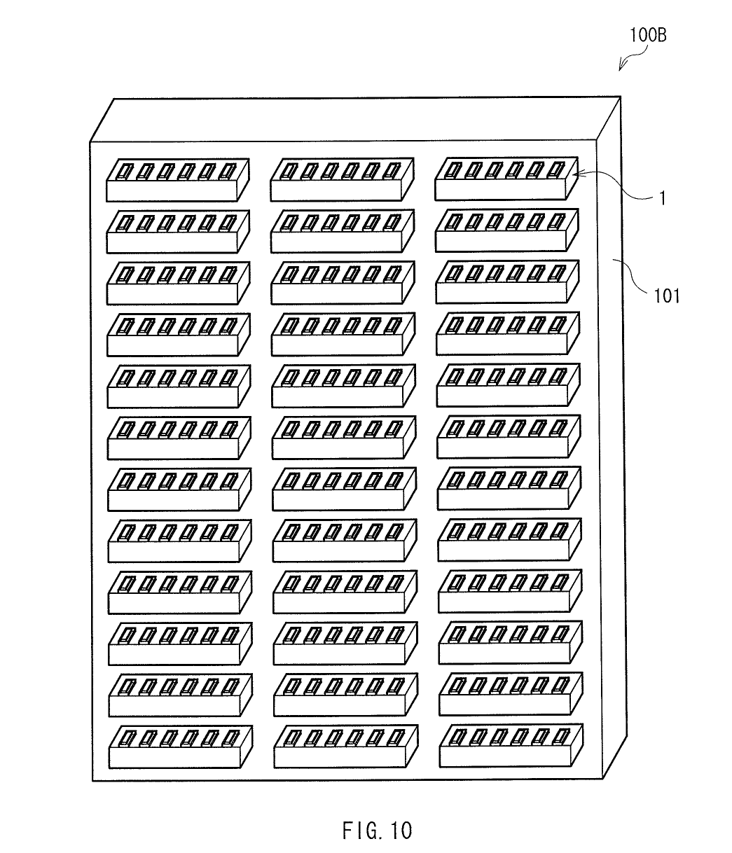

FIG. 10 illustrates a configuration example of a laser diode unit 100B using the laser diode arrays 1 and 2 according to the above-described embodiment and the above-described modification. In the laser diode unit 100B, for example, the above-described laser diode arrays 1 are two-dimensionally arranged along directions the same as and orthogonal to the direction where the devices 10 are mounted on the heat sink 20.

As described above, the laser diode units 100A and 100B according to the embodiment are allowed to achieve high power through one-dimensionally or two-dimensionally arranging the above-described laser diode arrays 1 and 2. Moreover, when the laser diode arrays 1 and 2 with different central wavelengths are combined and arranged, the oscillation wavelengths of the entire laser diode units 100A and 100B are allowed to be further increased. More specifically, for example, in the laser diode unit 100B illustrated in FIG. 10, the laser diode arrays 1 may be arranged in decreasing order of central wavelength from an upper-left stage toward the direction where the devices 10 are mounted, and may be arranged in increasing order of central wavelength from the upper-left stage toward a bottom stage. In particular, when the wavelength widths of the entire laser diode units 100A and 100B are about 4 nm or more, speckle noise is effectively reduced.

Although the present disclosure is described referring to the embodiment and the modification, the disclosure is not limited thereto, and may be variously modified. For example, the material and thickness of each layer, the method and conditions of forming each layer are not limited to those described in the above-described embodiment and the like, and each layer may be made of any other material with any other thickness by any other method under any other conditions. For example, in the above-described embodiment, the case where semiconductor layers including the active layer 12D are formed by an MOCVD method is described; however, the semiconductor layers may be formed by any other metal organic chemical vapor deposition method such as an MOVPE method, an MBE (Molecular Beam Epitaxy) method, or the like.

In addition, for example, in the above-described embodiment and the like, the specific configuration of the laser diode device (the device 10) is described; however, it is not necessary for the laser diode device to include all of the layers described in the above-described embodiment and the like, and the laser diode device may further include any other layer.

Moreover, the disclosure is applicable to not only the AlGaInP-based device 10 described in the above-described embodiment and the like but also a blue or blue-violet laser diode made of a nitride-based Group III-V compound semiconductor including at least gallium (Ga) from Group III elements and at least nitrogen (N) from Group V elements, a higher-power laser diode, a laser diode with any other oscillation wavelength, and a laser diode made of any other material.

It is to be noted that the present technology is allowed to have the following configurations.

(1) A laser diode array including:

a heat dissipator;

a plurality of submounts disposed independently of one another on the heat dissipator; and

a plurality of laser diode devices including two or more kinds of laser diode devices with different oscillation wavelengths, the laser diode devices being disposed on the respective submounts, and being electrically connected to one another.

(2) The laser diode array according to (1), in which the plurality of laser diode devices are arranged at equal intervals.

(3) The laser diode array according to (1) or (2), in which the plurality of laser diode devices are arranged at intervals of about 2 mm to about 10 mm both inclusive.

(4) The laser diode array according to any one of (1) to (3), in which a half-width of a superimposition of wavelength spectra of the plurality of laser diode devices is about 2 nm or more.

(5) The laser diode array according to any one of (1) to (4), in which the plurality of laser diode devices are electrically connected to one another in series.

(6) The laser diode array according to any one of (1) to (4), in which the plurality of laser diode devices are electrically connected to one another in parallel.

(7) The laser diode array according to any one of (1) to (6), in which the plurality of laser diode devices are configured of the same material-based devices.

(8) The laser diode array according to any one of (1) to (7), in which the laser diode devices are made of an AlGaInP-based material.

(9) The laser diode array according to (7), in which the laser diode devices are made of a GaN-based material.

(10) The laser diode array according to any one of (1) to (9), in which the plurality of laser diode devices include two or more kinds of laser diode devices with different stripe widths.

(11) The laser diode array according to any one of (1) to (10), in which the plurality of laser diode devices each have a pair of resonator facets at two facing side surfaces, and include two or more kinds of laser diode devices with different resonator lengths.

(12) The laser diode array according to any one of (1) to (11), further including a base plate for fixing,

in which a surface different from a surface where the laser diode devices are mounted of the heat dissipator is fixed on the base plate.

(13) The laser diode array according to any one of (1) to (11), further including a base plate for fixing,

in which a surface inclined at about 90° from a surface where the laser diode devices are mounted of the heat dissipator is fixed on the base plate.

(14) The laser diode array according to any one of (1) to (13), in which the submounts are made of an insulating material.

(15) A laser diode unit including a plurality of laser diode arrays, each of the laser diode arrays including:

a heat dissipator;

a plurality of submounts disposed independently of one another on the heat dissipator; and

a plurality of laser diode devices including two or more kinds of laser diode devices with different oscillation wavelengths, the laser diode devices being disposed on the respective submounts, and being electrically connected to one another.

(16) The laser diode unit according to (15), in which the plurality of laser diode arrays are disposed along a direction orthogonal to a direction where the plurality of laser diode devices are arranged.

(17) The laser diode unit according to (15) or (16), in which the plurality of laser diode arrays are arranged along directions the same as and orthogonal to a direction where the plurality of laser diode devices are arranged.

(18) The laser diode unit according to any one of (15) to (17), in which a half-width of a superimposition of wavelength spectra of the plurality of laser diode arrays is about 4 nm or more.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A laser diode array comprising:
a heat dissipator;
a plurality of submounts disposed independently of one another on the heat dissipator; and
a plurality of laser diode devices including two or more kinds of laser diode devices with different oscillation wavelengths, the laser diode devices being disposed on the respective submounts, and being electrically connected to one another.

2. The laser diode array according to claim 1, wherein the plurality of laser diode devices are arranged at equal intervals.

3. The laser diode array according to claim 1, wherein the plurality of laser diode devices are arranged at intervals of about 2 mm to about 10 mm both inclusive.

4. The laser diode array according to claim 1, wherein a half-width of a superimposition of wavelength spectra of the plurality of laser diode devices is about 2 nm or more.

5. The laser diode array according to claim 1, wherein the plurality of laser diode devices are electrically connected to one another in series.

6. The laser diode array according to claim 1, wherein the plurality of laser diode devices are electrically connected to one another in parallel.

7. The laser diode array according to claim 1, wherein the plurality of laser diode devices are configured of the same material-based devices.

8. The laser diode array according to claim 1, wherein the laser diode devices are made of an AlGaInP-based material.

9. The laser diode array according to claim 1, wherein the laser diode devices are made of a GaN-based material.

10. The laser diode array according to claim 1, wherein the plurality of laser diode devices include two or more kinds of laser diode devices with different stripe widths.

11. The laser diode array according to claim 1, wherein the plurality of laser diode devices each have a pair of resonator facets at two facing side surfaces, and include two or more kinds of laser diode devices with different resonator lengths.

12. The laser diode array according to claim 1, further comprising a base plate for fixing,
wherein a surface different from a surface where the laser diode devices are mounted of the heat dissipator is fixed on the base plate.

13. The laser diode array according to claim 1, further comprising a base plate for fixing,
wherein a surface inclined at about 90° from a surface where the laser diode devices are mounted of the heat dissipator is fixed on the base plate.

14. The laser diode array according to claim 1, wherein the submounts are made of an insulating material.

15. A laser diode unit including a plurality of laser diode arrays, each of the laser diode arrays comprising:
a heat dissipator;
a plurality of submounts disposed independently of one another on the heat dissipator; and
a plurality of laser diode devices including two or more kinds of laser diode devices with different oscillation wavelengths, the laser diode devices being disposed on the respective submounts, and being electrically connected to one another.

16. The laser diode unit according to claim 15, wherein the plurality of laser diode arrays are disposed along a direction orthogonal to a direction where the plurality of laser diode devices are arranged.

17. The laser diode unit according to claim 15, wherein the plurality of laser diode arrays are arranged along directions the same as and orthogonal to a direction where the plurality of laser diode devices are arranged.

18. The laser diode unit according to claim 15, wherein a half-width of a superimposition of wavelength spectra of the plurality of laser diode arrays is about 4 nm or more.
